(19) United States
(12) Patent Application Publication
(10) Pub. No.: US 2025/0299916 A1
(43) Pub. Date: Sep. 25, 2025

(54) FOCUSED ION BEAM APPARATUS AND CONTROL METHOD THEREOF

(71) Applicant: Kioxia Corporation, Tokyo (JP)

(72) Inventors: Mitsuo KOIKE, Mie Mie (JP); Seekei LEE, Kawasaki Kanagawa (JP); Kazuya HATANO, Nagoya Aichi (JP); Shiro TAKENO, Yokohama Kanagawa (JP)

(21) Appl. No.: 19/059,887

(22) Filed: Feb. 21, 2025

(30) Foreign Application Priority Data
Mar. 19, 2024 (JP) 2024-043095

(51) Int. Cl. H01J 37/304; H01J 37/20; H01J 37/285

(52) U.S. Cl. CPC H01J 37/304; H01J 37/20; H01J 37/285

(57) ABSTRACT

A focused ion beam apparatus includes a controller configured to: define an actual working space defined by a scanning point of an electron beam and a focusing distance of the electron beam; irradiate a sample with the electron beam using an electron beam column and acquire a plurality of electron microscope images of the sample with different observation orientations, respectively; create a three-dimensional model including real space information of the sample based on the plurality of electron microscope images; change an attitude of the sample; acquire, from the three-dimensional model, a two-dimensional image of the sample; determine a predetermined range to be irradiated with an ion beam using the two-dimensional image; and process the sample by irradiating the predetermined range with the ion beam using an ion beam column.

### CROSS-REFERENCE TO RELATED APPLICATION

This application is based upon and claims the benefit of priority from Japanese Patent Application No. 2024-043095, filed Mar. 19, 2024, the entire contents of which are incorporated herein by reference.

### FIELD

Embodiments described herein relate generally to a focused ion beam apparatus and a control method thereof.

### BACKGROUND

In today's world of miniaturization and increasing complexity of semiconductor devices, defect analysis to identify the causes of malfunctions and failures in semiconductor devices is becoming increasingly important. Among these, transmission electron microscope (TEM) observation is widely used for structural analysis as a method that allows for highly accurate observation of minute areas within a sample.

In recent years, TEM sample preparation technology using a focused ion beam (FIB) has been attracting attention. By using a focused ion beam apparatus, a focused ion beam formed by focusing metal ions or the like to the nanometer level can be applied onto a sample surface, thereby enabling the sample surface to be precisely processed. By detecting secondary electrons emitted when a focused ion beam is applied onto a sample surface, it is possible to observe the surface using a scanning ion microscope (SIM) image. For this reason, for example, processing is performed using a focused ion beam while observing a SIM image.

In addition, a focused ion beam apparatus combined with a scanning electron microscope (SEM) may be used to check the degree of processing of a sample by the focused ion beam.

### DESCRIPTION OF THE DRAWINGS

FIG. 1 is a schematic view of a focused ion beam apparatus according to a first embodiment.

FIG. 2 is a schematic view showing an example of a diaphragm for an electron beam e used in the focused ion beam apparatus according to the first embodiment.

FIG. 3 is a schematic view showing a relationship between a focal depth of an SEM and a SIM image.

FIGS. 4A to 4D are schematic views showing an example of a diaphragm in a plane perpendicular to the plane through which the electron beam e passes, which is used to make the focal depth shallow in an electron beam column of the present embodiment.

FIG. 5 is a flowchart of a control method of the focused ion beam apparatus according to the present embodiment.

FIG. 6 is a schematic view showing an example of a three-dimensional model including real space information of a sample S.

FIGS. 7A and 7B are schematic views of a sample holder according to a second embodiment.

FIGS. 8A to 8C are schematic views of a sample holder according to the second embodiment.

FIG. 9 is a schematic view of a sample holder according to the second embodiment.

### DETAILED DESCRIPTION

Embodiments provide a focused ion beam apparatus and a control method thereof that are capable of easily processing a sample.

In general, according to one embodiment, there is provided a focused ion beam apparatus including: an electron beam column configured to irradiate a sample with an electron beam having a focal depth; an ion beam column configured to process the sample by irradiating the sample with an ion beam; a detector configured to detect electrons generated from the sample; a sample holder configured to hold the sample and tilt the sample with respect to the electron beam and the ion beam; and a controller configured to: define an actual working space defined by a scanning point of the electron beam and a focusing distance of the electron beam; irradiate the sample with the electron beam using the electron beam column and acquire a plurality of electron microscope images of the sample, the plurality of electron microscope images having different observation orientations, respectively; create a three-dimensional model including real space information of the sample based on the plurality of electron microscope images; change an attitude of the sample in accordance with an operation of the sample holder; acquire, from the three-dimensional model, a two-dimensional image of the sample when viewed from an irradiation axis of the ion beam; determine a predetermined range to be irradiated with the ion beam using the two-dimensional image; and process the sample by irradiating the predetermined range with the ion beam using the ion beam column.

Hereinafter, embodiments will be described with reference to drawings. In the drawings, the same or similar parts are denoted by the same or similar reference numerals.

In the present specification, in order to indicate a positional relationship of components and the like, an upper direction of a drawing is described as “up”, and a lower direction of the drawing is described as “down”. In the present specification, the concepts of “up” and “down” are not necessarily terms indicating a relationship with the direction of gravity.

### First Embodiment

A focused ion beam apparatus according to the present embodiment includes: an electron beam column that irradiates a sample with an electron beam having a shallow focal depth; an ion beam column that processes the sample by irradiating the sample with an ion beam; a detector that detects electrons generated from the sample; a sample holder that holds the sample and capable of tilting the sample with respect to the electron beam and the ion beam; and a control unit that defines an actual working space defined by a scanning point of the electron beam and a focusing distance of the electron beam, irradiates the sample with the electron beam using the electron beam column and acquires a plurality of electron microscope images of the sample having different observation orientations, creates a three-dimensional model including real space information of the sample based on the plurality of electron microscope images, changes an attitude of the sample in accordance with an operation of the sample holder, acquires, from the three-dimensional model, a two-dimensional image of the sample when viewed from an irradiation axis of the ion beam, determines a predetermined range to be irradiated with the ion beam using the two-dimensional image, and processes the sample by irradiating the predetermined range with the ion beam using the ion beam column.

A control method of a focused ion beam apparatus according to the present embodiment includes: by using an electron beam column that irradiates a sample with an electron beam having a shallow focal depth, an ion beam column that processes the sample by irradiating the sample with an ion beam, a detector that detects electrons generated from the sample, and a sample holder that holds the sample and capable of tilting the sample with respect to the electron beam and the ion beam, defining an actual working space defined by a scanning point of the electron beam and a focusing distance of the electron beam; irradiating the sample with the electron beam using the electron beam column and acquiring a plurality of electron microscope images of the sample having different observation orientations; creating a three-dimensional model including real space information of the sample based on the plurality of electron microscope images; changing an attitude of the sample in accordance with an operation of the sample holder; acquiring, from the three-dimensional model, a two-dimensional image of the sample when viewed from an irradiation axis of the ion beam; determining a predetermined range to be irradiated with the ion beam using the two-dimensional image; and processing the sample by irradiating the predetermined range with the ion beam using the ion beam column. A virtual space and a three-dimensional model are displayed on a display unit 34. An operator can see this and operate it.

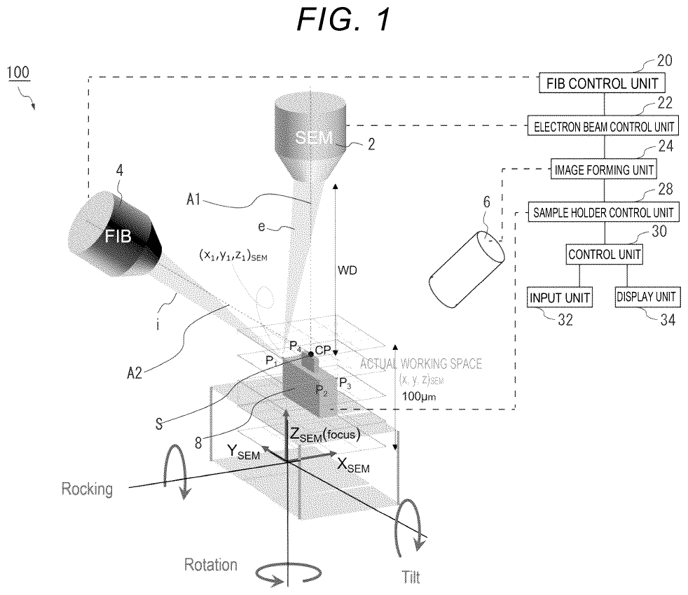

FIG. 1 is a schematic view of a focused ion beam apparatus 100 according to the present embodiment.

The focused ion beam apparatus 100 includes an electron beam column 2, an ion beam column 4, a secondary electron detector 6, a sample holder 8, an FIB control unit (or FIB controller) 20, an electron beam control unit (or electron beam controller) 22, an image forming unit 24, a sample holder control unit 28, a control unit (or controller) 30, an input unit 32, and a display unit 34.

The sample holder 8 is disposed inside a sample chamber (not shown). A sample S is disposed on the sample holder 8. The sample holder control unit 28 rotates, moves, and the like the sample holder 8. Thereby, the sample S is controlled to an attitude for irradiation with an electron beam e, an attitude for irradiation with an ion beam i, or another attitude. In controlling such an attitude, for example, rotation in a plane perpendicular to an X_{SEM} axis (rocking), rotation in a plane perpendicular to a Y_{SEM} axis (tilt), and rotation in a plane perpendicular to a Z_{SEM} axis (rotation) are performed.

The sample S is irradiated with the electron beam e from the electron beam column 2. Moreover, the sample S is irradiated with the ion beam i from the ion beam column 4. An irradiation axis A1 of the electron beam e from the electron beam column 2 and an irradiation axis A2 of the ion beam i from the ion beam column 4 intersect with each other at a predetermined angle on the surface of the sample S, for example. Here, the predetermined angle is, for example, greater than 50 degrees and less than 60 degrees. However, the predetermined angle is not particularly limited thereto.

The electron beam control unit 22 controls the electron beam column 2. The FIB control unit 20 controls the ion beam column 4.

The secondary electron detector 6 detects secondary electrons generated from the sample S by irradiation with the electron beam e or ion beam i.

The image forming unit 24 forms an electron microscope image using a signal for scanning the electron beam e sent from the electron beam control unit 22 to the electron beam column 2 and a signal of the secondary electrons detected by the secondary electron detector 6. The display unit 34 can display, for example, an electron microscope image.

In addition, the image forming unit 24 forms a SIM image using a signal for scanning the ion beam i sent from the FIB control unit 20 to the ion beam column 4 and a signal of secondary electrons detected by the secondary electron detector 6. The display unit 34 can display, for example, a SIM image.

The display unit 34 is, for example, a display device such as a liquid crystal monitor.

For example, the operator inputs conditions related to the control of the focused ion beam apparatus 100 into the input unit 32. The input unit 32 transmits input information to the control unit 30. The input unit 32 is, for example, a keyboard connected to a computer. The input unit 32 may be, for example, a semiconductor memory or the like in which conditions related to the control of the focused ion beam apparatus 100 are stored.

The control unit 30 can control the FIB control unit 20, the electron beam control unit 22, the image forming unit 24, the sample holder control unit 28, the input unit 32, and the display unit 34. The control unit 30, the FIB control unit 20, the electron beam control unit 22, the image forming unit 24, and the sample holder control unit 28 are, for example, electronic circuits. The control unit 30, the FIB control unit 20, the electron beam control unit 22, the image forming unit 24, and the sample holder control unit 28 are, for example, computers configured with a combination of hardware such as an arithmetic circuit and software such as a program.

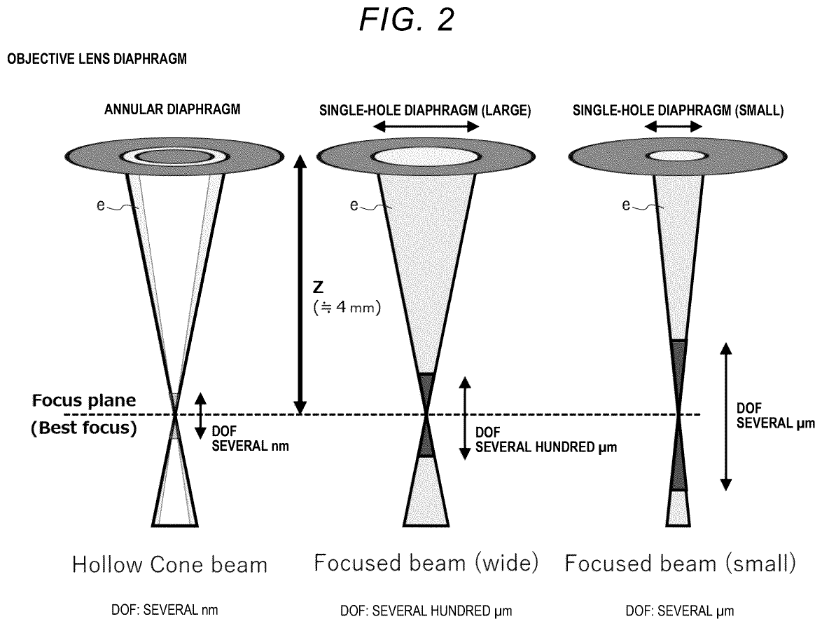

FIG. 2 is a schematic view showing an example of a diaphragm for the electron beam e used in the focused ion beam apparatus 100 according to the present embodiment.

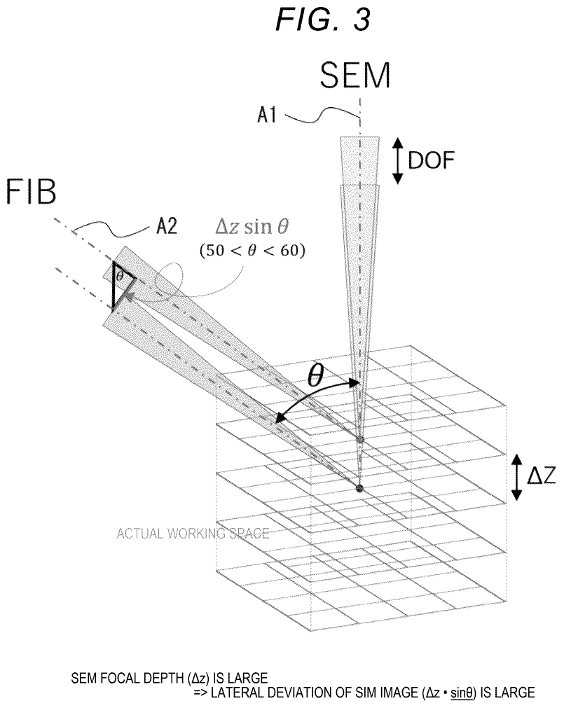

FIG. 3 is a schematic view showing a relationship between a focal depth of an SEM and a SIM image.

As an example of a comparative embodiment of the present embodiment, a case is considered in which a sample S is observed using a small aperture (single-hole diaphragm (small)) and an electron beam e (focused beam) having a small convergence angle, as shown on the right side of FIG. 2. In this case, a focal depth Δz (DOF: Depth Of Field) of the SEM becomes very deep, about several μm. This makes it difficult to recognize the change in depth of the sample S. Here, as shown in FIG. 3, when the angle between the irradiation axis A1 of the electron beam e and the irradiation axis A2 of the ion beam i is denoted by θ, the lateral deviation of the SIM image (the direction perpendicularly intersecting the irradiation axis A2 of the ion beam) can be expressed as Δz·sin θ. Therefore, when Δz is large, it becomes difficult to process the sample S using the ion beam i.

As an example of a comparative embodiment of the present embodiment, a case is considered in which a large aperture (single-hole diaphragm (large)) is used as shown in the center of FIG. 2 to increase the depth resolution, thereby enabling irradiation with an electron beam e (focused beam) having a large convergence angle. This makes it possible to reduce the spread of the beam at the focal position in the depth direction, thereby increasing the lateral resolution of the SIM image. Furthermore, since the electron beam e becomes thicker even if it is slightly deviated from the focal position, the sensitivity to out-of-focus can be increased. The focal depth is small, about several hundred nm.

In the present embodiment, a hollow cone beam using an annular diaphragm as shown on the left side of FIG. 2 is used. This corresponds to the case where, from the electron beam e formed using a large aperture as shown in the center of FIG. 3, only the outer electron beam e is extracted without using the inner electron beam e. Accordingly, since the inner electron beam e, which is a factor in widening the focal depth, is not used, the focal depth can be made shallow, for example, to 10 nm or less (about several nm).

Moreover, it is preferable that the focal depth of the electron beam e is shallower than the thickness of the sample.

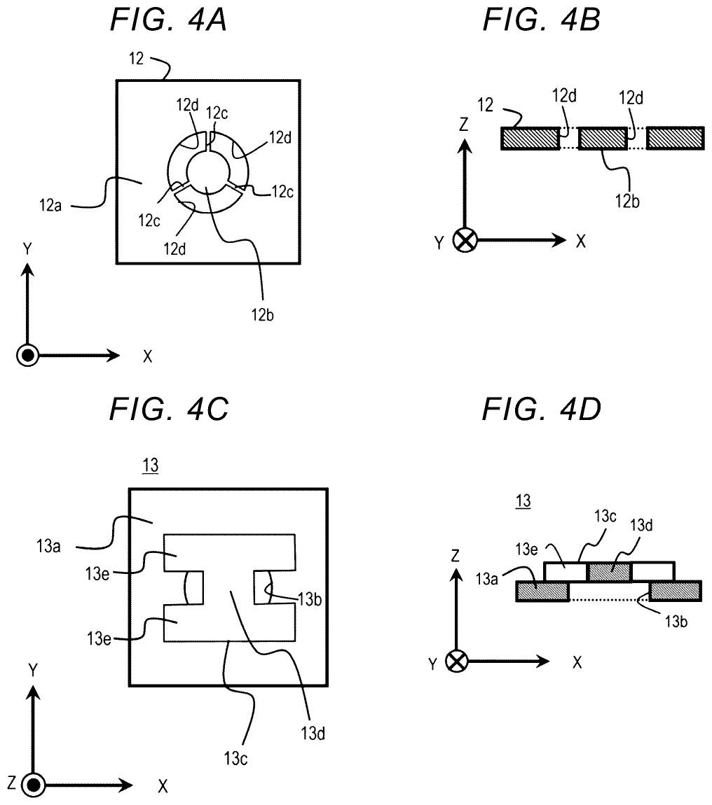

FIGS. 4A to 4D are schematic views showing examples of a diaphragm in a plane perpendicular to the plane through which the electron beam e passes, which is used to make the focal depth shallow in the electron beam column 2 of the present embodiment.

FIGS. 4A and 4B show an annular diaphragm 12, which is an example for forming a hollow cone beam in the embodiment. The annular diaphragm 12 includes a plate portion 12a on the outer circumferential side, a central portion 12b on the inner circumferential side, and a plurality of bridges 12c connecting the plate portion 12a and the central portion 12b. When the annular diaphragm 12 is irradiated with the electron beam e in a Z-axis direction, the electron beam e passes through the plate portion 12a, the central portion 12b, and an opening (gap) 12d without the bridge 12c. This blocks the central portion of the conical beam and forms a hollow cone beam. The number and arrangement of the bridges 12c are not limited to those shown in the drawing, and can be changed as appropriate.

FIGS. 4C and 4D show a block-equipped single-hole diaphragm 13 for forming a pseudo hollow cone beam. The block-equipped single-hole diaphragm 13 includes a single-hole diaphragm 13a and a block 13c. The single-hole diaphragm 13a has an opening 13b. An H-shaped block 13c is provided above the opening 13b of the single-hole diaphragm 13a. The block 13c has a central portion 13d whose dimension is smaller than the opening 13b, and support portions 13e which are provided on both sides of the central portion 13d and whose dimension is larger than the opening 13b. With this arrangement, when the block-equipped single-hole diaphragm 13 is irradiated with the electron beam e in the Z-axis direction, the electron beam e passes through an area of the opening 13b that is not blocked by the block 13c. This allows only the portions of the irradiated conical beam that correspond to a plurality of openings (gaps) to pass through, forming a pseudo hollow cone beam with no central portion.

It is noted that the shape of the diaphragm that can be preferably used in the present embodiment is not limited to the above.

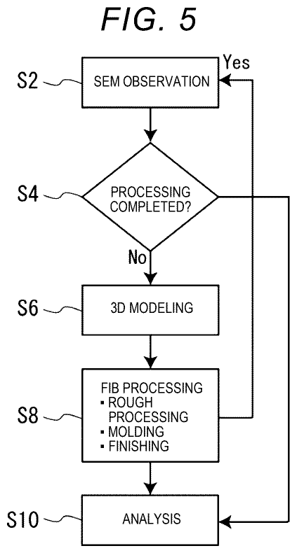

FIG. 5 is a flowchart of a control method of the focused ion beam apparatus according to the present embodiment.

First, inside a sample chamber not shown in FIG. 1, an actual working space (first space) is defined around the position (cross point: CP) where the irradiation axis A1 of the electron beam e and the irradiation axis A2 of the ion beam i intersect, the actual working space being defined by a scanning point of the electron beam e (SEM coordinates: X_{SEM} and Y_{SEM} in FIG. 1) and a focusing distance of the electron beam e (SEM focal distance: Z_{SEM} (focus)). The size of the actual working space is, for example, about 100 μm in each of the X_{SEM} direction, Y_{SEM} direction, and Z_{SEM} direction. The definition of such an actual working space is performed by the control unit 30, for example.

It is preferable to use the sample holder 8 to dispose the surface of the sample S in the area where the irradiation axis A1 of the electron beam column 2 and the irradiation axis A2 of the ion beam column intersect.

When defining the actual working space defined by the scanning point and the focusing distance of the electron beam e, it is preferable to correct the irradiation position of the ion beam i by irradiating the surface of the sample with the ion beam i.

Next, the sample holder 8 is controlled by, for example, the sample holder control unit 28 or the control unit 30 to control (change) the attitude of the sample S to an appropriate attitude for observing the shape of the sample S using the electron beam e.

Next, the sample S is irradiated with an electron beam e using the electron beam column 2. Then, an electron microscope image of the sample S is acquired using the image forming unit 24. Furthermore, the attitude of the sample S is controlled (changed) and an electron microscope image of the sample S is acquired. In this manner, a plurality of electron microscope images of the sample S are acquired (S2 in FIG. 5).

Generally, the processing of the sample S by FIB is performed while checking the shape of the sample S by using an electron microscope. When it is determined after acquiring and checking the electron microscope image that processing of the sample S is completed (S4 in FIG. 5), the sample S is analyzed, for example, using a TEM (S10 in FIG. 5).

When the processing of the sample S is not completed, a three-dimensional model including real space information of the sample S is created based on the plurality of acquired electron microscope images (S6 in FIG. 5). The creation of such a three-dimensional model is performed, for example, in the control unit 30. It is also possible to use a computer configured by combining hardware such as electronic circuits and arithmetic circuits, such as the “three-dimensional model creation unit” connected to the control unit 30, with software such as programs.

By comparing the secondary electron intensities in this manner for a plurality of electron microscope images, the secondary electron intensities can be used to ascertain the relative height and lateral relationships for the sample S. That is, it is possible to ascertain the three-dimensional shape of the sample S, including information on the actual working space (in real space).

Next, the created three-dimensional model is displayed in a virtual space (virtual reality (VR) space, second space). Here, the virtual space is a space having, for example, an X-axis direction, a Y-axis direction, and a Z-axis direction, similarly to the actual working space. For example, the X-axis direction, the Y-axis direction, and the Z-axis direction of the virtual space can be set in the same directions as the X_{SEM}-axis direction, the Y_{SEM}-axis direction, and the Z_{SEM}-axis direction of the actual working space. The created three-dimensional model of the sample S can then be disposed in the virtual space at the same position as the sample S in the actual working space.

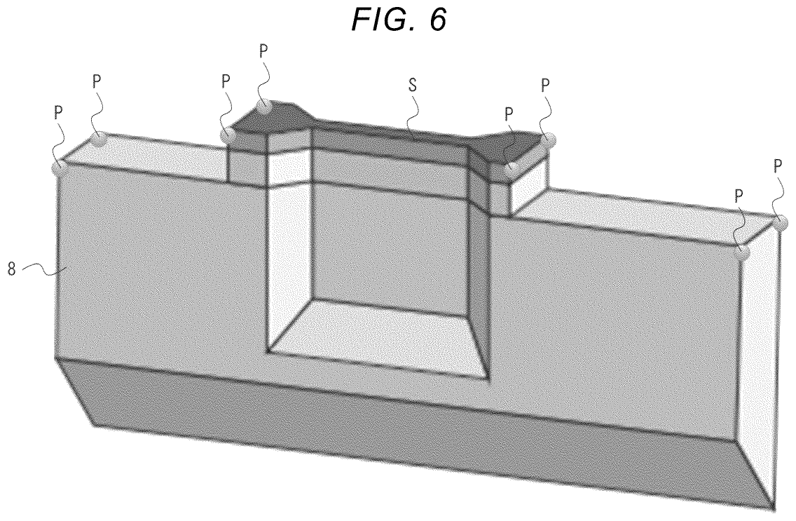

Here, when creating a three-dimensional model including real space information of the sample S, it is preferable to use a feature point P of the sample S. As the feature point, for example, a portion whose shape is relatively easy to understand, such as the edge of the sample S, and which is not directly related to the observation area, is used. This is because it is easier to ascertain the shape of the sample S by using such feature points. Also, this makes it easy to dispose the created three-dimensional model of the sample S in the virtual space at the same position as the sample S in the actual working space. FIG. 6 is a schematic view showing an example of a three-dimensional model including real space information of the sample S. In addition, FIG. 6 also shows a location in the three-dimensional model that corresponds to the sample holder 8, a location in the three-dimensional model that corresponds to the feature point P, and a location in the three-dimensional model that corresponds to the sample S.

For example, the created three-dimensional model may be displayed on the display unit 34.

Next, the sample S is processed by the ion beam i. First, the attitude of the sample S is changed using the sample holder control unit 28, and controlled to an appropriate attitude for processing by the ion beam i.

Next, a two-dimensional image of the surface of the sample S when viewed from the irradiation axis A2 of the ion beam i is acquired from the above three-dimensional model.

Next, a two-dimensional image of the surface of the sample S is used to determine a predetermined range to be irradiated with the ion beam. Here, it is preferable to control the sample holder 8 such that the focusing point of the ion beam is positioned on the surface of the sample defined by a predetermined range.

Next, the sample S is processed by irradiating a predetermined range with an ion beam (S8 in FIG. 5). The processing of the sample S may be repeated several times, for example, through “rough processing”, “molding”, and “finishing”. In that case, the steps from S2 to S8 in FIG. 5 may be repeated several times.

In other words, in the focused ion beam apparatus and the control method of the focused ion beam apparatus according to the present embodiment, the three-dimensional model displayed in the virtual space is used instead of a SIM image to process the sample S.

Next, the effects of the control method of the focused ion beam apparatus according to the present embodiment will be described.

When processing is performed using the ion beam i, a predetermined range (processing frame) to be irradiated with the ion beam i is set on the surface of the sample S, and then processing is performed. Here, in order to set a predetermined range (processing frame) to be irradiated with the ion beam i on the surface of the sample S, observation of the surface of the sample S is required. In general, the resolution of a SIM image is lower than that of a SEM image. Therefore, when observing the sample S, the resolution of the SIM image is insufficient, which can make it difficult to recognize the shape.

In particular, when observing the sample S using a SIM image in order to perform finishing processing of the sample S, the sample S is irradiated with an ion beam i at a low acceleration voltage in order to prevent processing damage to the sample S caused by irradiation with the ion beam i. However, the resolution of the SIM image acquired by the ion beam i at a low acceleration voltage is low. This makes it difficult to recognize the sample S, and causes a problem that it is difficult to set a predetermined range (processing frame) to be irradiated with the ion beam i.

Furthermore, as described above, since it is difficult to set a predetermined range (processing frame) to be irradiated with the ion beam, the sample S is sometimes prepared while repeating short-time ion beam processing and observation using SIM images. In this case, there is a problem that the preparation time of the sample S becomes long.

Therefore, in the control method of the focused ion beam apparatus according to the present embodiment, a three-dimensional model including real space information of the sample S is created using a high-resolution electron microscope image. Then, based on this three-dimensional model, processing is performed using an ion beam i. Specifically, a two-dimensional image of the surface of the sample S when viewed from the irradiation axis A2 of the ion beam i is acquired from the three-dimensional model. Since it is based on a high-resolution electron microscope image, the sample S can be processed with high precision. In addition, processing damage to the sample S caused by irradiation with an ion beam during SIM image observation can be prevented. Therefore, it is possible to provide a focused ion beam apparatus and a control method thereof that are capable of easily processing a sample.

Here, by using an electron beam e having a shallow focal depth, as described above, it is possible to make the focal depth shallow, for example, to 10 nm or less (about several nm). This makes it possible to improve the resolution in the depth direction. For example, by passing the electron beam e through an annular diaphragm to form a hollow cone beam, it is possible to form the electron beam e having a focal depth of, for example, 10 nm or less. Moreover, the electron beam e may be passed through a plurality of openings.

Moreover, it is preferable that the focal depth of the electron beam e is shallower than the thickness of the sample S. This is because when the focal depth of the electron beam e is deeper than the thickness of the sample S, the resolution of the SEM image in the depth direction is too low compared to the thickness of the sample S, making it difficult to process the sample S in the depth direction.

It is preferable to control the sample holder 8 such that the focusing point of the ion beam is positioned on the surface of the sample defined by a predetermined range, since this allows processing to be performed with high precision.

It is also preferable to use the sample holder 8 to dispose the surface of the sample S in the area where the irradiation axis A1 of the electron beam column 2 and the irradiation axis A2 of the ion beam column 4 intersect. This is because when the surface of the sample S is not disposed in the area where the irradiation axis A1 of the electron beam column 2 and the irradiation axis A2 of the ion beam column 4 intersect, there is a high likelihood of there being a deviation between the place irradiated with the ion beam and the two-dimensional image of the sample S acquired from the three-dimensional model when viewed from the irradiation axis A2 of the ion beam, making it difficult to perform precise processing.

When defining the actual working space defined by the scanning point and the focusing distance of the electron beam e, it is preferable to correct the irradiation position of the ion beam by irradiating the surface of the sample with the ion beam. This is to prevent positional deviation, for example at the degree of nanometers, between the sample S in the actual working space and the three-dimensional model of the sample in the virtual space.

With the focused ion beam apparatus and the control method thereof according to the present embodiment, it is possible to provide a focused ion beam apparatus and a control method thereof that are capable of easily processing a sample.

### Second Embodiment

A focused ion beam apparatus and a control method thereof according to the present embodiment differ from the focused ion beam apparatus and control method thereof according to the first embodiment in that the sample S can be rotated within a plane that perpendicularly intersects a plane including the irradiation axis A1 of the electron beam e and the irradiation axis A2 of the ion beam i. Here, description of contents that overlap with the first embodiment will be omitted.

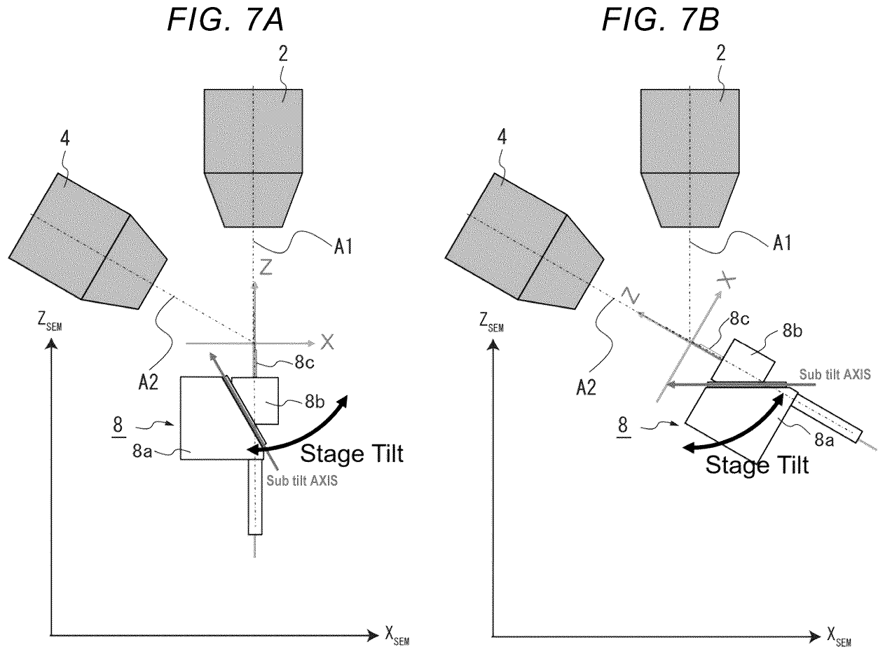

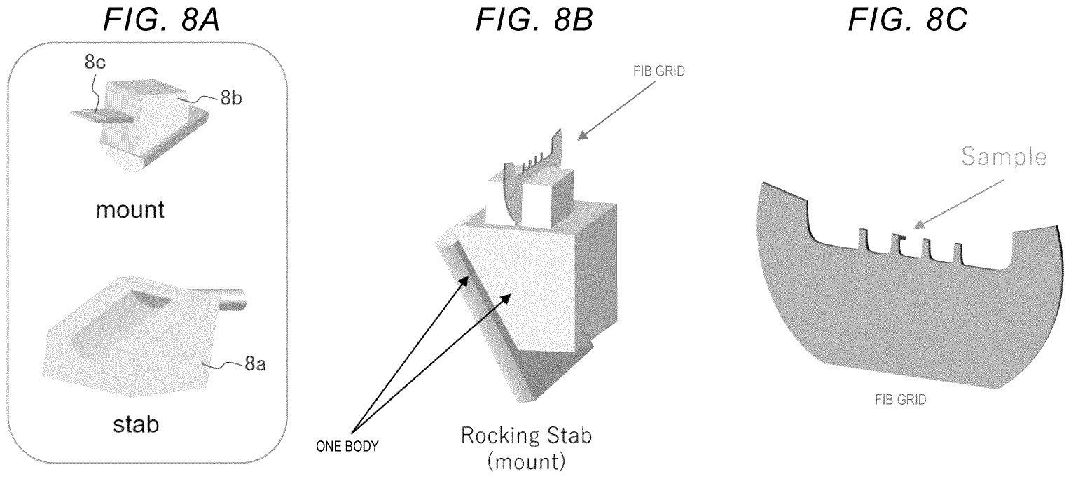

FIGS. 7A to 9 are schematic views showing the sample holder 8 used in the present embodiment. The sample holder 8 has a stab 8a, a mount 8b, and an FIB grid 8c. As shown in FIG. 8B, the FIB grid 8c is fixed to a mount 8b. As shown in FIG. 8C, the sample S is fixed to the tip of an FIB grid 8c. The sample holder 8 is rotatable within a plane including the X_{SEM} axis and the Z_{SEM} axis. In FIG. 7A, a sample S (not shown) fixed to an FIB grid 8c is disposed along the irradiation axis A1 of the electron beam e. In FIG. 7B, a sample S (not shown) fixed to an FIB grid 8c is disposed along the irradiation axis A2 of the ion beam i.

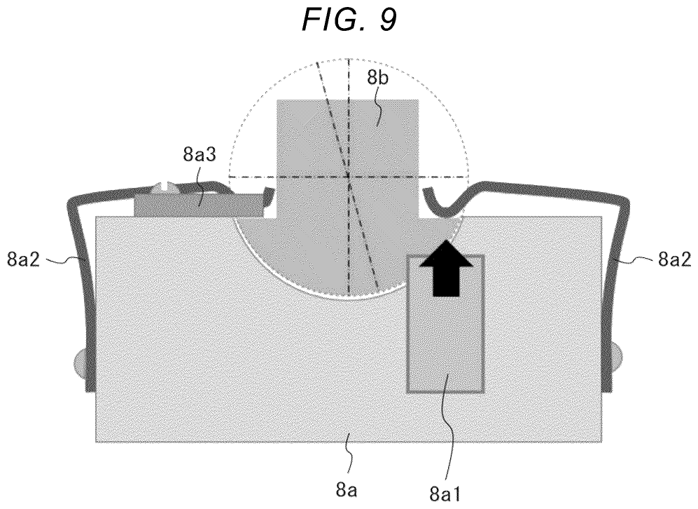

For example, as shown in FIG. 8A, the stab 8a has a semi-cylindrical gap. A semi-cylindrical portion of the mount 8b is fitted into such a gap. As shown in FIG. 9, for example, the mount 8b is fixed by a leaf spring 8a2. As shown in FIG. 9, a piezoelectric element 8al can expand and contract in the vertical direction to rotate the mount 8b. Furthermore, for example, a fastener 8a3 is provided to position the mount 8b when the expansion and contraction of the piezoelectric element 8al returns to its original extent.

By using the sample holder 8 used in the present embodiment, it becomes easy to acquire a plurality of electron microscope images having different observation orientations. Therefore, the practicality of processing the sample S using the three-dimensional model is improved.

The focused ion beam apparatus and the control method thereof according to the present embodiment also make it possible to provide a focused ion beam apparatus and a control method thereof that are capable of easily processing a sample.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A focused ion beam apparatus comprising:
an electron beam column configured to irradiate a sample with an electron beam having a focal depth;
an ion beam column configured to process the sample by irradiating the sample with an ion beam;
a detector configured to detect electrons generated from the sample;
a sample holder configured to hold the sample and tilt the sample with respect to the electron beam and the ion beam; and
a controller configured to:
define an actual working space defined by a scanning point of the electron beam and a focusing distance of the electron beam;
irradiate the sample with the electron beam using the electron beam column and acquire a plurality of electron microscope images of the sample, the plurality of electron microscope images having different observation orientations, respectively;
create a three-dimensional model including real space information of the sample based on the plurality of electron microscope images;
change an attitude of the sample in accordance with an operation of the sample holder;
acquire, from the three-dimensional model, a two-dimensional image of the sample when viewed from an irradiation axis of the ion beam;
determine a predetermined range to be irradiated with the ion beam using the two-dimensional image; and
process the sample by irradiating the predetermined range with the ion beam using the ion beam column.

2. The focused ion beam apparatus according to claim 1, wherein, after creating the three-dimensional model including the real space information of the sample based on the plurality of electron microscope images, the three-dimensional model is displayed in a virtual space before the attitude of the sample is changed in accordance with the operation of the sample holder.

3. The focused ion beam apparatus according to claim 1, wherein the controller is further configured to control the sample holder by changing the attitude of the sample in accordance with the operation of the sample holder such that a focusing point of the ion beam is positioned on a surface of the sample defined by the predetermined range.

4. The focused ion beam apparatus according to claim 1, wherein the controller is further configured to, when defining the actual working space defined by the scanning point and the focusing distance of the electron beam, correct an irradiation position of the ion beam by irradiating a surface of the sample with the ion beam using the ion beam column.

5. The focused ion beam apparatus according to claim 1, wherein the electron beam includes a hollow cone beam.

6. The focused ion beam apparatus according to claim 1, wherein the electron beam column has a plurality of openings through which the electron beam passes.

7. The focused ion beam apparatus according to claim 1, wherein the focal depth of the electron beam in a direction of irradiation of the electron beam is shallower than a thickness of the sample.

8. A control method of a focused ion beam apparatus, the control method comprising:
by using an electron beam column configured to irradiate a sample with an electron beam having a shallow focal depth, an ion beam column configured to process the sample by irradiating the sample with an ion beam, a detector configured to detect electrons generated from the sample, and a sample holder configured to hold the sample and capable of tilting the sample with respect to the electron beam and the ion beam,
defining an actual working space defined by a scanning point of the electron beam and a focusing distance of the electron beam;
irradiating the sample with the electron beam using the electron beam column and acquiring a plurality of electron microscope images of the sample having different observation orientations, respectively;
creating a three-dimensional model including real space information of the sample based on the plurality of electron microscope images;
changing an attitude of the sample in accordance with an operation of the sample holder;
acquiring, from the three-dimensional model, a two-dimensional image of the sample when viewed from an irradiation axis of the ion beam;
determining a predetermined range to be irradiated with the ion beam using the two-dimensional image; and
processing the sample by irradiating the predetermined range with the ion beam using the ion beam column.

9. The control method of a focused ion beam apparatus according to claim 8, wherein, after creating the three-dimensional model including the real space information of the sample based on the plurality of electron microscope images, the three-dimensional model is displayed in a virtual space before the attitude of the sample is changed in accordance with the operation of the sample holder.
